(19) United States
(12) Patent Application Publication
(10) Pub. No.: US 2018/0044357 A1
(43) Pub. Date: Feb. 15, 2018

(54) PROCESS FOR THE GENERATION OF THIN INORGANIC FILMS

(71) Applicant: BASF SE, Ludwigshafen (DE)

(72) Inventors: Jan SPIELMANN, Mannheim (DE); Falko ABELS, Roemerberg (DE); Florian BLASBERG, Frankfurt (DE); Katharina FEDERSEL, Eppelheim (DE); Christian SCHILDKNECHT, Neustadt (DE); Daniel LOEFFLER, Birkenheide (DE); Torben ADERMANN, Heidelberg (DE); Juergen FRANK, Ludwigshafen (DE); Kerstin SCHIERLE-ARNDT, Zwingenberg (DE); Sabine WEIGUNY, Freinsheim (DE)

(73) Assignee: BASF SE, Ludwigshafen (DE)

(21) Appl. No.: 15/557,178

(22) PCT Filed: Mar. 2, 2016
(86) PCT No.: PCT/EP2016/054371

§ 371 Date: Sep. 11, 2017

(30) Foreign Application Priority Data
Mar. 12, 2015 (EP) 15158835.7

(51) Int. Cl. C07F 7/08; C23C 16/455; C23C 16/18; C09D 1/00

(52) U.S. Cl. CPC C07F 7/0814; C09D 1/00; C23C 16/45553; C23C 16/18

(57) ABSTRACT

The present invention is in the field of processes for the generation of thin inorganic films on substrates. In particular the present invention relates to a process comprising bringing a com-pound of general formula (I) into the gaseous or aerosol state Lₙ-M-XₘL=formula and depositing the compound of general formula (I) from the gaseous or aerosol state onto a solid substrate, wherein R¹, R², R³, R⁴, are independent of each other hydrogen, an alkyl group, an aryl group, or a SiA₃ group with A being an alkyl or aryl group, and at least two of R¹, R², R³, R⁴ are a SiA₃ group, n is an integer from 1 to 4, M is a metal or semimetal, X is a ligand which coordinates M, and m is an integer from 0 to 4.

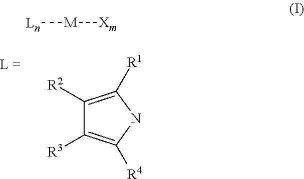

The present invention is in the field of processes for the generation of thin inorganic films on substrates, in particular atomic layer deposition processes.

With the ongoing miniaturization, e.g. in the semiconductor industry, the need for thin inorganic films on substrates increases while the requirements of the quality of such films become stricter. Thin inorganic films serve different purposes such as barrier layer, seeds, liners, dielectric, separator of fine structures or as electric contact. Several methods for the generation of thin inorganic films are known. One of them is the deposition of film forming compounds from the gaseous state on a substrate. In order to bring metal or semimetal atoms into the gaseous state at moderate temperatures, it is necessary to provide volatile precursors, e.g. by complexation the metals or semimetals with suitable ligands. These ligands need to be removed after deposition of the complexed metals or semimetals onto the substrate.

EP 2 256 121 Al discloses volatile group 2 metal precursors comprising polyfunctionalized pyrrolyl anions coordinated to a metal and their use in atomic layer deposition.

It was an object of the present invention to provide a process for the generation of inorganic films of high quality and reproducibility on solid substrates under economically feasible conditions. It was desired that this process can be performed with as little decomposition of the precursor comprising the metal as possible before it is in contact with the solid substrate. At the same time it was desired to provide a process in which the precursor is easily decomposed after deposited on a solid substrate. It was also aimed at providing a process using metal precursors which can easily be modified and still remain stable in order to fit the precursor's properties to the particular needs.

These objects were achieved by a process comprising bringing a compound of general formula (I) into the gaseous or aerosol state

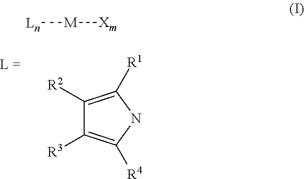

and depositing the compound of general formula (I) from the gaseous or aerosol state onto a solid substrate, wherein

R¹, R², R³, R⁴, are independent of each other hydrogen, an alkyl group, an aryl group, or a SiA₃ group with A being an alkyl or aryl group, and at least two of R¹, R², R³, R⁴ are a SiA₃ group, n is an integer from 1 to 4,

M is a metal or semimetal,

X is a ligand which coordinates M, and

m is an integer from 0 to 4.

The present invention further relates to a compound of general formula (I), wherein

R¹, R², R³, R⁴, are independent of each other hydrogen, an alkyl group, an aryl group, or a SiA₃ group with A being alkyl or aryl group, and at least two of R¹, R², R³, R⁴ are a SiA₃ group,

n is an integer from 1 to 4,

M is metal or semimetal,

X is a ligand which coordinates M, and

m is an integer from 0 to 4.

The present invention further relates to a compound of general formula (II)

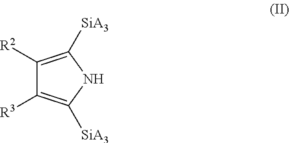

wherein A is an alkyl or an aryl group, R² and R³ are independent of each other hydrogen, an alkyl group, an aryl group, or a SiA₃ group with A being alkyl or aryl group.

The present invention further relates to the use of a compound of general formula (I), wherein

R¹, R², R³, R⁴, are independent of each other hydrogen, an alkyl group, an aryl group, or a SiA₃ group with A being an alkyl or aryl group, and at least two of R¹, R², R³, R⁴ are a SiA₃ group,

n is an integer from 1 to 4,

M is a metal or semimetal,

X is a ligand which coordinates M, and

m is an integer from 0 to 4

for a film formation process on a solid substrate.

Preferred embodiments of the present invention can be found in the description and the claims. Combinations of different embodiments fall within the scope of the present invention.

In the process according to the present invention a compound of general formula (I) is brought into the gaseous or aerosol state. R¹, R², R³, R⁴, are independent of each other hydrogen, an alkyl group, an aryl group, or a SiA₃ group with A being an alkyl or aryl group, and at least two of R¹, R², R³, R⁴ are a SiA₃ group.

An alkyl group can be linear or branched. Examples for a linear alkyl group are methyl, ethyl, n-propyl, n-butyl, n-pentyl, n-hexyl, n-heptyl, n-octyl, n-nonyl, n-decyl. Examples for a branched alkyl group are iso-propyl, iso-butyl, sec-butyl, tent-butyl, 2-methyl-pentyl, 2-ethyl-hexyl, cyclopropyl, cyclohexyl, indanyl, norbornyl. Preferably, the alkyl group is a C₁ to C₈ alkyl group, more preferably a C₁ to C₆ alkyl group, in particular a C₁ to C₄ alkyl group. Alkyl groups can be substituted for example by halogens like fluoride, chloride, bromide, iodide; by pseudohalogens like cyanide, cyanate, thiocyanate; by alcohols; by alkoxygroups such as methoxy or ethoxy; or by trialkylsilyl groups such as trimethylsilyl or dimethyl-tent-butylsilyl. A preferred example for a trial-kylsilyl-substituted alkyl group is trimethylsilyl methyl.

Aryl groups include aromatic hydrocarbons such as phenyl, naphthalyl, anthrancenyl, phenanthrenyl groups and heteroaromatic groups such as pyrryl, furanyl, thienyl, pyridinyl, quinoyl, benzofuryl, benzothiophenyl, thienothienyl. Several of these groups or combinations of these groups are also possible like biphenyl, thienophenyl or furanylthienyl. Aryl groups can be substituted for example by halogens like fluoride, chloride, bromide, iodide; by pseudohalogens like cyanide, cyanate, thiocyanate; by alcohols; by alkyl chains; by alkoxy chains; or by triakylsilyl-groups. Aromatic hydrocarbons are preferred, phenyl is more preferred.

The group SiA₃ can contain all the same A or different A. It is possible that all A are the same or that two A are the same and one is different or that all three A are different to each other. The same definitions for alkyl and aryl groups apply as described above. Examples for a SiA₃ group with the same alkyl groups are trimethylsilyl, triethylsilyl, tri-n-propylsilyl, tri-iso-propylsilyl, tricyclohexylsilyl. Examples for a trialkylsilyl group with different alkyl groups are dimethyl-tert-butylsilyl, dimethylcyclohexylsilyl, methyl-di-iso-propylsilyl. Examples for a SiA₃ group in which A is both alkyl and aryl group are phenyl-dimethylsilyl or diphenylmethylsilyl.

Preferably, R¹ and R⁴ are independent of each other a SiA₃ group, more preferably R¹ and R⁴ are independent of each other a SiA₃ group and R² and R³ are hydrogen, even more preferably, R¹ and R⁴ are the same SiA₃ group and R² and R³ are hydrogen.

The ligand L can be protonated at the nitrogen atom or it can be not protonated. Preferably, L is not protonated.

It is preferred that the molecular weight of the compound of general formula (I) is up to 1000 g/mol, more preferred up to 800 g/mol, in particular up to 600 g/mol.

The compound of general formula (I) according to the present invention can contain 1 to 4 ligands L, i.e. n is 1 to 4. The number of ligands depends upon the metal or semimetal M. Small ions such as earth alkali metals typically accommodate up to 2 ligands L while larger ions such as titanium or ruthenium can accommodate 4 ligands L. Preferably, n is 1 or 2, in particular 2. If n is 2 or larger the ligands L can be the same or different to each other, preferably they are the same.

According to the present invention M in the compound of general formula (I) can be any metal or semimetal. Metals include earth alkaline metals such as Be, Mg, Ca, Sr, Ba; main group metals such as Al, Ga, In, Sn, Tl, Pb, Bi; transition metals such as Sc, Ti, V, Cr, Mn, Fe, Co, Ni, Cu, Zn, Y, Zr, Nb, Mo, Tc, Ru, Rh, Pd, Ag, Cd, Hf, Ta, W, Re, Os, Ir, Pt, Au, Hg, Tl, Pb or Bi; lanthanoids such as La, Ce, Pr, Nd, Pm, Sm, Eu, Gd, Tb, Dy, Ho, Er, Tm, Yb, Lu. Semimetals include B, Si, Ge, As, Sb. Preferred metals are Sr, Ba, Ni or Co.

The metal or semimetal M can be in any oxidation state. Preferably M is close to the oxidation state in which it is supposed to be in the final film on the solid substrate. For example, if a metal or semimetal film of oxidation state 0 is desired, the metal or semimetal M in the compound of general formula (I) should preferably be in the oxidation state 0 or −1 or +1 as long as a stable compound of general formula (I) is available. Otherwise the next higher or lower oxidation state is chosen with which a stable compound of general formula (I) can be obtains, such as −2 or +2. Furthermore, if a metal oxide film is desired in which the metal has the oxidation state +2, it is preferable that the metal or semimetal M in the compound of general formula (I) is in the oxidation state +1, +2, or +3. Another example is a metal oxide film in which the metal shall have the oxidation state +4. In this case, M in the compound of general formula (I) should preferable be in the oxidation state +4 or +3 or +5. More preferably, M in the compound of general formula (I) has the same oxidation state as it is supposed to be in the final film on the solid substrate. In this case no oxidation or reduction is necessary.

According to the present invention the ligand X in the compound of general formula (I) can be any ligand which coordinates M. If X bears a charge, m is normally chosen such that the compound of general formula (I) is neutrally charged. If more than one such ligand is present in the compound of general formula (I), i.e. m>1, they can be the same or different from each other. If m is 3, it is possible that two ligands X are the same and the remaining X is different from these. X can be in any ligand sphere of the metal or semimetal M, e.g. in the inner ligand sphere, in the outer ligand sphere, or only loosely associated to M. It is further possible that if more than one ligands X are present in the compound of general formula (I) the ligands X are in different ligand spheres. Preferably, X is in the inner ligand sphere of M.

The ligand X in the compound of general formula (I) according to the present invention includes anions of halogens like fluoride, chloride, bromide or iodide and pseudohalogens like cyanide, isocyanide, cyanate, isocyanate, thiocyanate, isothiocyanate, or azide. Furthermore, X can be any amine ligand in which the coordinating nitrogen atom is either aliphatic like in dialkylamine, piperidine, morpholine, or hexamethyldisilazane; amino imides; aromatic like in pyrrole, indole, pyridine, or pyrazine. The nitrogen atom of the amine ligand is often deprotonated before coordinated to M. Furthermore, X can be an amide ligand such as formamide or acetamide; an amidinate ligand such as acetamidine; or a guanidinate ligand such guanidine. It is also possible that X is a ligand in which an oxygen atom coordinates to the metal or semimetal. Examples are alkanolates, tetrahydrofurane, acetylacetonate, acetyl acetone, 1,1,1,5,5,5-hexafluoroacety-lacetonate, or 1,2-dimethoxyethane. Other suitable examples for X include both a nitrogen and an oxygen atom which both coordinate to M including dimethylamino-iso-propanol. Also suitable for X are ligands which coordinate via a phosphorous atom to M. These include trialkyl phosphines such as trimethyl phosphine, tri-tert-butyl phosphine, tricyclohexyl phosphine, or aromatic phosphines such as triphenyl phosphine, or tritolylphosphine.

Further suitable ligands X are alkylanions like methyl, ethyl, propyl, butyl, or neopentyl anions as well as silicon bearing alkyl groups such as trimethylsilyl methyl. X can also be an unsaturated hydrocarbon which coordinates with the Tr-bond to M. Unsaturated hydrocarbons include ethylene, propylene, iso-butylene, cyclohexene, cyclooctadiene, ethyne, propyne. Terminal alkynes can relatively easily be deprotonated. Then they can coordinate via the terminal carbon atom bearing the negative charge. X can also be an unsaturated anionic hydrocarbon which can coordinate both via the anion and the unsaturated bond such as allyl or 2-methyl-allyl. Cyclopentadienyl anions and substituted cyclopentadienyl anions are also suitable for X. Further suitable examples for X are carbonmonoxide (CO) or nitric oxide (NO). Further suitable for X are carbene ligands, for example N-heterocyclic carbenes such as N,N-dialklylimidazol-2-ylidene or non-cyclic carbenes such as bis(dialkylamino)methylidene.

It is also possible to use molecules which contain multiple atoms which coordinate to M. These include amidinates such as acetamidine or N,N′-bis-iso-propylacetamidine; guanidinates such as guanidine; aminoimines such as 2-N-tert-butylamino-2-methylpropanal-N-tertbuylimine; diimines such as glyoxal-N,N′-bis-isopropyl-diimine, glyoxal-N,N′-bis-tert-butyl-diimine or 2,4-pentanedione-diimine; diketiminates such as N,N′-2,4-pentanediketiminate; iminopyrroles including pyrrol-2-carbald-alkylimines such as pyrrol-2-carbald-ethylimine, pyrrol-2-carbald-iso-propylimine or pyrrol-2-carbald-tert-butylimine as well as pyrrol-2,5-biscarbald-alkyldiimines such as pyrrol-2,5-biscarbald-tert-butyldiimine. Further examples are bipyridine, o-terpyridine, ethylenediamine, substituted ethylenediamine, ethylenedi(bisphenylphosphine), ethylene-di(bis-tert-butylphosphine).

Small ligands which have a low vaporization temperature are preferred for X. These preferred ligands include carbonmonoxide, cyanide, ethylene, tetrahydrofurane, dimethylamine, trimethylphosphine, nitric oxide and 1,2-dimethoxyethane. Small anionic ligands which can easily be transformed into volatile neutral compounds upon protonation, for example by surface-bound protons, are preferred for X. Examples include methyl, ethyl, propyl, dimethylamide, diethylamide, allyl, 2-methyl-allyl.

The compound of general formula (I) can form dimers or oligomers via coordinating bonds. A process comprising these dimers or oligomers also falls within the scope of the present invention.

The compound of general formula (I) used in the process according to the present invention is used at high purity to achieve the best results. High purity normally means that the substance used contains at least 90 wt.-% compound of general formula (I), preferably at least 95 wt.-% compound of general formula (I), more preferably at least 98 wt.-% compound of general formula (I), in particular at least 99 wt.-% compound of general formula (I). The purity can be determined by elemental analysis according to DIN 51721 (Prüfung fester Brennstoffe—Bestimmung des Gehaltes an Kohlenstoff and Wasserstoff—Verfahren nach Radmacher-Hoverath, August 2001) or preferably by inductively coupled plasma mass spectrometry (ICP-MS) according to ISO 17294-1:2004, in particular to determine the amount of undesired metals.

In the process according to the present invention the compound of general formula (I) is brought into the gaseous or aerosol state. This can be achieved by heating the compound of general formula (I) to elevated temperatures. In any case a temperature below the decomposition temperature of the compound of general formula (I) has to be chosen. Preferably, the heating temperature ranges from slightly above room temperature to 300° C., more preferably from 30° C. to 250° C., even more preferably from 40° C. to 200° C., in particular from 50° C. to 150° C.

Another way of bringing the compound of general formula (I) into the gaseous or aerosol state is direct liquid injection (DLI) as described for example in US 2009/0 226 612 Al. In this method the compound of general formula (I) is typically dissolved in a solvent and sprayed in a carrier gas or vacuum. Depending on the vapor pressure of the compound of general formula (I), the temperature and the pressure the compound of general formula (I) is either brought into the gaseous state or into the aerosol state. Various solvents can be used provided that the compound of general formula (I) shows sufficient solubility in that solvent such as at least 1 g/l, preferably at least 10 g/l, more preferably at least 100 g/l. Examples for these solvents are coordinating solvents such as tetrahydrofuran, dioxane, diethoxyethane, pyridine or non-coordinating solvents such as hexane, heptane, benzene, toluene, or xylene. Solvent mixtures are also suitable. The aerosol comprising the compound of general formula (I) should contain very fine liquid droplets or solid particles. Preferably, the liquid droplets or solid particles have a weight average diameter of not more than 500 nm, more preferably not more than 100 nm. The weight average diameter of liquid droplets or solid particles can be determined by dynamic light scattering as described in ISO 22412:2008. It is also possible that a part of the compound of general formula (I) is in the gaseous state and the rest is in the aerosol state, for example due to a limited vapor pressure of the compound of general formula (I) leading to partial evaporation of the compound of general formula (I) in the aerosol state.

It is preferred to bring the compound of general formula (I) into the gaseous or aerosol state at decreased pressure. In this way, the process can usually be performed at lower heating temperatures leading to decreased decomposition of the compound of general formula (I). It is also possible to use increased pressure to push the compound of general formula (I) in the gaseous or aerosol state towards the solid substrate. Often, an inert gas, such as nitrogen or argon, is used as carrier gas for this purpose. Preferably, the pressure is 10 bar to 10⁻⁷ mbar, more preferably 1 bar to 10⁻³ mbar, in particular 1 to 0.01 mbar, such as 0.1 mbar.

In the process according to the present invention a compound of general formula (I) is deposited on a solid substrate from the gaseous or aerosol state. The solid substrate can be any solid material. These include for example metals, semimetals, oxides, nitrides, and polymers. It is also possible that the substrate is a mixture of different materials. Examples for metals are aluminum, steel, zinc, and copper. Examples for semimetals are silicon, germanium, and gallium arsenide. Examples for oxides are silicon dioxide, titanium dioxide, and zinc oxide. Examples for nitrides are silicon nitride, aluminum nitride, titanium nitride, and gallium nitride. Examples for polymers are polyethylene terephthalate (PET), polyethylene naphthalene-dicarboxylic acid (PEN), and polyamides.

The solid substrate can have any shape. These include sheet plates, films, fibers, particles of various sizes, and substrates with trenches or other indentations. The solid substrate can be of any size. If the solid substrate has a particle shape, the size of particles can range from below 100 nm to several centimeters, preferably from 1 μm to 1 mm. In order to avoid particles or fibers to stick to each other while the compound of general formula (I) is deposited onto them, it is preferably to keep them in motion. This can, for example, be achieved by stirring, by rotating drums, or by fluidized bed techniques.

The deposition takes place if the substrate comes in contact with the compound of general formula (I). Generally, the deposition process can be conducted in two different ways: either the substrate is heated above or below the decomposition temperature of the compound of general formula (I). If the substrate is heated above the decomposition temperature of the compound of general formula (I), the compound of general formula (I) continuously decomposes on the surface of the solid substrate as long as more compound of general formula (I) in the gaseous or aerosol state reaches the surface of the solid substrate. This process is typically called chemical vapor deposition (CVD). Usually, an inorganic layer of homogeneous composition, e.g. the metal or the metal or semimetal oxide or nitride, is formed on the solid substrate as the organic material is desorbed from the metal or semimetal M. Typically the solid substrate is heated to a temperature in the range of 300 to 1000° C., preferably in the range of 350 to 600° C.

Alternatively, the substrate is below the decomposition temperature of the compound of general formula (I). The solid substrate can be at a temperature higher than, equal to, or lower than the temperature of the place where the compound of general formula (I) is brought into the gaseous or aerosol state. Preferably, the temperature of the substrate is at least 30° C. lower than the decomposition temperature of the compound of general formula (I). Preferably, the temperature of the substrate is from room temperature to 400° C., more preferably from 100 to 300° C., such as 150 to 220° C.

The deposition of compound of general formula (I) onto the solid substrate is either a physisorption or a chemisorption process. Preferably, the compound of general formula (I) is chemisorbed on the solid substrate. One can determine if the compound of general formula (I) chemisorbs to the solid substrate by exposing a quartz microbalance with a quartz crystal having the surface of the substrate in question to the compound of general formula (I) in the gaseous or aerosol state. The mass increase is recorded by the eigen frequency of the quartz crystal. Upon evacuation of the chamber in which the quartz crystal is placed the mass should not decrease to the initial mass, but about a monolayer of the residual compound of general formula (I) remains if chemisorption has taken place. In most cases where chemisorption of the compound of general formula (I) to the solid substrate occurs, the x-ray photoelectron spectroscopy (XPS) signal (ISO 13424 EN—Surface chemical analysis—X-ray photoelectron spectroscopy—Reporting of results of thin-film analysis; October 2013) of M changes due to the bond formation to the substrate.

If the temperature of the substrate in the process according to the present invention is kept below the decomposition temperature of the compound of general formula (I), typically a mono-layer is deposited on the solid substrate. Once a molecule of general formula (I) is deposited on the solid substrate further deposition on top of it usually becomes less likely. Thus, the deposition of the compound of general formula (I) on the solid substrate preferably represents a self-limiting process step. The typical layer thickness of a self-limiting deposition processes step is from 0.01 to 1 nm, preferably from 0.02 to 0.5 nm, more preferably from 0.03 to 0.4 nm, in particular from 0.05 to 0.2 nm. The layer thickness is typically measured by ellipsometry as described in PAS 1022 DE (Referenzverfahren zur Bestimmung von optischen and dielektrischen Materialeigenschaften sowie der Schichtdicke dünner Schichten mittels Ellipsometrie; February 2004).

Often it is desired to build up thicker layers than those just described. In order to achieve this in the process according to the present invention it is preferable to decompose the deposited compound of general formula (I) by removal of all L and X after which further compound of general formula (I) is deposited. This sequence is preferably performed at least twice, more preferably at least 10 times, in particular at least 50 times. Removing all L and X in the context of the present invention means that at least 95 wt.-% of the total weight of L and X in the deposited compound of general formula (I) are removed, preferably at least 98 wt.-%, in particular at least 99 wt.-%. The decomposition can be effected in various ways. The temperature of the solid substrate can be increased above the decomposition temperature.

Furthermore, it is possible to expose the deposited compound of general formula (I) to a plasma like an oxygen plasma or a hydrogen plasma; to oxidants like oxygen, oxygen radicals, ozone, nitrous oxide (N₂O), nitric oxide (NO), nitrogendioxde (NO₂) or hydrogenperoxide; to reductants like hydrogen, ammonia, alcohols, hydroazine, dialkylhydrazine or hydroxylamine; or solvents like water. It is preferable to use oxidants, plasma or water to obtain a layer of a metal oxide or a semimetal oxide, preferably water, an oxygen plasma, an oxygen radicals, ozone, nitrous oxide, nitric oxide, or nitrogen dioxide. Exposure to water, an oxygen plasma or ozone is more preferred, in particular water. If layers of elemental metal or semimetal are desired it is preferable to use reducing agents. Preferred examples are hydrogen, hydrogen radicals, hydrogen plasma, ammonia, ammonia radicals, ammonia plasma, hydrazine, N,N-dimethylhydrazine, silane, disilane, trisilane, cyclopentasilane, cyclohexasilane, dimethylsilane, diethylsilane, phenylsilane, or trisilylamine; more preferably hydrogen, hydrogen radicals, hydrogen plasma, ammonia, ammonia radicals, ammonia plasma, hydrazine, N,N-dimethylhydrazine, silane; in particular hydrogen. The reducing agent can either directly cause the decomposition of the deposited compound of general formula (I) or it can be applied after the decomposition of the deposited compound of general formula (I) by a different agent, for example water. For layers of metal nitrides it is preferable to use ammonia or hydrazine. Small molecules are believed to easily access the metal or semimetal M due to the planarity of the aromatic part of ligand L which is the consequence of the conjugation of the two iminomethyl groups to the pyrrole unit in ligand L. Typically, a low decomposition time and high purity of the generated film is observed.

A deposition process comprising a self-limiting process step and a subsequent self-limiting reaction is often referred to as atomic layer deposition (ALD). Equivalent expressions are molecular layer deposition (MLD) or atomic layer epitaxy (ALE). Hence, the process according to the present invention is preferably an ALD process. The ALD process is described in detail by George (Chemical Reviews 110 (2010), 111-131).

A particular advantage of the process according to the present invention is that the compound of general formula (I) is very versatile, so the process parameters can be varied in a broad range. Therefore, the process according to the present invention includes both a CVD process as well as an ALD process.

After decomposition of the compound of general formula (I) deposited on the solid substrate, further compound of general formula (I) can be deposited on top to further increase the film thickness on the solid substrate. Preferably, the sequence of depositing the compound of general formula (I) onto a solid substrate and decomposing the deposited compound of general formula (I) is performed at least twice. This sequence can be repeated many times, for example 10 to 500, such as 50 or 100 times. Usually, this sequence is not repeated more often than 1000 times. In this way films of a defined and uniform thickness are accessible. Typical films generated by repeating the above sequence have a thickness of 0.5 to 50 nm. It is possible to run each sequence with the same compound of general formula (I) or with different compounds of general formula (I) or with one or more compounds of general formula (I) and one or more metal or semimetal precursors different from general formula (I). For example, if the first, third, fifth and so on sequence is carried out with a compound of general formula (I) wherein M is Ba and every second, fourth, sixth and so on sequence is carried out with a Ti precursor such as a titanocene complex, i.e. either a compound of general formula (I) or a different Ti comprising compound, it is possible to generate films of BaTiO₃.

Depending on the number of sequences of the process according to the present invention, films of various thicknesses are generated. Ideally, the thickness of the film is proportional to the number of sequences performed. However, in practice some deviations from proportionality are observed for the first 30 to 50 sequences. It is assumed that irregularities of the surface structure of the solid substrate cause this non-proportionality.

One sequence of the process according to the present invention can take from milliseconds to several minutes, preferably from 0.1 second to 1 minute, in particular from 1 to 10 seconds. The longer the solid substrate at a temperature below the decomposition temperature of the compound of general formula (I) is exposed to the compound of general formula (I) the more regular films formed with less defects.

The present invention also relates to a compound of general formula (I). The same definitions and preferred embodiments as for the process apply as applicable for the compound of general formula (I). The present invention also relates to a compound of general formula (II). The same definitions and preferred embodiments as for the process apply as applicable for the compound of general formula (II).

The process according to the present invention yields films. A film can be only one monolayer of deposited compound of formula (I), several consecutively deposited and decomposed layers of the compound of general formula (I), or several different layers wherein at least one layer in the film was generated by using the compound of general formula (I). A film can contain defects like holes. These defects, however, generally constitute less than half of the surface area covered by the film. The film is preferably an inorganic film. In order to generate an inorganic film, all organic ligands L and X have to be removed from the film as described above. More preferably, the film is an elemental metal film. The film can have a thickness of 0.1 nm to 1 μm or above depending on the film formation process as described above. Preferably, the film has a thickness of 0.5 to 50 nm. The film preferably has a very uniform film thickness which means that the film thickness at different places on the substrate varies very little, usually less than 10%, preferably less than 5%. Furthermore, the film is preferably a conformal film on the surface of the substrate. Suitable methods to determine the film thickness and uniformity are XPS or ellipsometry.

The film obtained by a process according to the present invention can be used in an electronic element. The electronic elements can have structural features of various sizes, for example from 100 nm to 100 μm. The process for forming the films for the electronic elements is particularly well suited for very fine structures. Therefore, electronic elements with sizes below 1 μm are preferred. Examples for electronic elements are field-effect transistors (FET), solar cells, light emitting diodes, sensors, or capacitors. In optical devices such as light emitting diodes or light sensors the film can for example serve to increase the reflective index of the layer which reflects light. An example for a sensor is an oxygen sensor, in which a film can serve as oxygen conductor, for example if a metal oxide film is prepared. In field-effect transistors out of metal oxide semiconductor (MOS-FET) the film can act as dielectric layer or as diffusion barrier. It is also possible to make semiconductor layers out of films in which elemental nickel-silicon is deposited on a solid substrate. Furthermore, a cobalt-containing film, e.g. elemental cobalt, can be deposited by the process according to the present invention, for example as a diffusion barrier for copper-based contacts, such as Cu—W alloys.

Preferred electronic elements are capacitors. The film made by the process according to the present invention has several possible functions in capacitors. It can for example act as dielectric or as interlayer between dielectric layer and conductive layer to enhance lamination. Preferably the film acts as dielectric in a capacitor.

Further preferred electronic elements are complex arrays of integrated circuits. The film has several possible functions in complex integrated circuits. It can for example act as interconnect or as interlayer between a conducting copper layer and an insulating metal oxide layer to decrease copper migration into the insulating layer. Preferably the film acts as interconnect in a field-effect transistor or as interlayer in electrical contacts in complex integrated circuits.

### EXAMPLES

All synthetic steps involving the synthesis or handling of metal complexes were conducted under inert conditions using oven-dried glassware, dry solvents and an inert argon or nitrogen atmosphere.

### Example 1

### Synthesis of the 2,5-bis(trimethylsilyl)-pyrrole

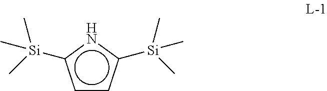

A solution of 2,2,6,6-tetramethylpiperidine (TMP) (161 g, 1.14 mol) in THF (500 mL) was cooled to −72° C. and n-butyllithium (451 ml, 1.13 mmol, 2.5 M in hexane) was added. The resulting suspension was allowed to stir for 30 minutes at −72° C. N-Boc-pyrrole (72.4 g, 0.433 mol) was added. The resulting solution was allowed to stir for 90 min at −72° C. and trimethylsilyl chloride (122 g, 1.13 mol) was added and allowed to stir for further 10 minutes at −72° C. The mixture was allowed to warm to room temperature and stirred overnight. The crude mixture was treated with 300 ml dist. water. Layers were separated and the combined organic layers were dried over Na₂SO₄, filtered off the drying agent and concentrated in vacuum to yield 159.5 g of the crude product which was subjected to the next transformation without further purification.

Deprotected pyrrole was obtained after pyrolysis of the carbamate at 20 mbar, 82-97° C.: 107 g of a colorless liquid was obtained which crystallized upon cooling to below room temperature.

¹H-NMR (400 MHz, THF-d₈): 9.77 (s, 1H), 6.32 (d, J=2.0 Hz, 2H), 0.22 (s, 18H).

### Example 2

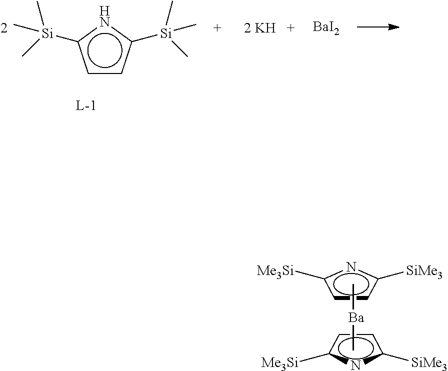

5 g (23.6 mmol) of ligand L-1 were dissolved in 30 ml of THF. 1 g (25.0 mmol) KH in 100 ml THF were added via a cannula and stirred at ambient temperature for 5 h. 4.62 g (11.8 mmol) Bal₂ in 150 ml THF were added via a cannula and stirred over night at ambient temperature. The resulting suspension was filtrated. The solvent of the filtrate was evaporated in vacuo. The slightly yellow oily residue was washed with n-hexane yielding 4.49 g crude product. 2.2 g of the crude product were purified by sublimation at 0.001 mbar and 180° C. yielding in 1.1 g of pure complex C-2.

¹H-NMR (THF-d₈, 360 MHz, 25° C.): δ (in ppm) 6.7 s (2H), 0.2 s (18H). Elemental analysis: found: C: 42.1, N: 4.9, H: 7.1, Ba: 23.4, Si: 18.8, calc.: C: 43.0, N: 5.0, H: 7.2, Ba: 24.6, Si: 20.1.

### Scheme for examples 3 and 4

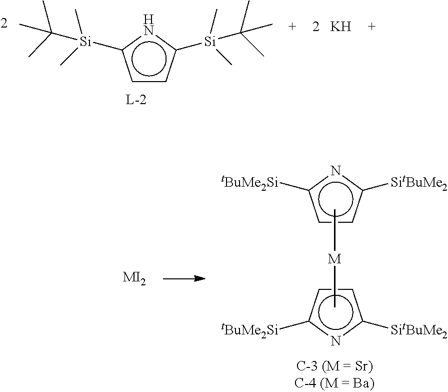

### Example 3

3 g (10.15 mmol) of ligand L-2 were dissolved in 50 ml of THF. 0.41 g (10.15 mmol) KH in 50 ml THF were added via a cannula and stirred at ambient temperature for 48 h. 1.73 g (5.07 mmol) Bal₂ in 80 ml THF were added via a cannula and stirred for 72 h at ambient temperature. The resulting suspension was filtrated. The solvent of the filtrate evaporated in vacuo.

¹H-NMR (THF-d₈, 500 MHz, 25° C.): δ (in ppm) 6.89 s (2H), 0.81 s (18H), 0.35 s (6H).

### Example 4

3 g (10.15 mmol) of ligand L-2 were dissolved in 50 ml of THF. 0.41 g (10.15 mmol) KH in 50 ml THF were added via a cannula and stirred at ambient temperature for 48 h. 1.98 g (5.07 mmol) Bal₂ in 80 ml THF were added via a cannula and stirred for 72 h at ambient temperature. The resulting suspension was filtered. The solvent of the filtrate evaporated in vacuo. The brown residue was washed with 20 ml of n-hexane yielding 1,6 g of complex C-4.

¹H-NMR (THF-d₈, 500 MHz, 25° C.): δ (in ppm) 6.84 s (2H), 0.85 s (18H), 0.33 s (6H).

1. A process comprising bringing a compound of general formula (I) into the gaseous or aerosol state 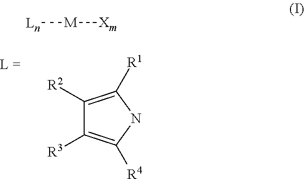
and depositing the compound of general formula (I) from the gaseous or aerosol state onto a solid substrate,
wherein R¹, R², R³, and R⁴ are independent of each other hydrogen, an alkyl group, an aryl group, or a SiA₃ group with A being an alkyl or aryl group, and at least two of R¹, R², R³, and R⁴ are a SiA₃ group,
n is an integer from 1 to 4,
M is a metal or semimetal,
X is a ligand which coordinates M, and
m is an integer from 0 to 4.

2. The process according to claim 1, wherein the compound of general formula (I) is chemisorbed on the surface of the solid substrate.

3. The process according to claim 1, wherein the deposited compound of general formula (I) is decomposed by removal of all ligands L and X.

4. The process according to claim 3, wherein the decomposition is effected by exposure to water, an oxygen plasma, an oxygen radical, ozone, nitrous oxide, nitric oxide, or nitrogen dioxide.

5. The process according to claim 3, wherein the decomposition is effected by hydrogen, hydrogen radicals, hydrogen plasma, ammonia, ammonia radicals, ammonia plasma, silane, hydrazine, N,N-dimethylhydrazine, disilane, trisilane, cyclopentasilane, cyclohexasilane, dimethyl silane, diethyl silane, phenyl silane, or trisilylamine.

6. The process according to claim 3, wherein a sequence of depositing the compound of general formula (I) onto a solid substrate and decomposing the deposited compound of general formula (1) is performed at least twice.

7. The process according to claim 1 wherein M is Sr, Ba, Ni or Co.

8. A compound of general formula (I) 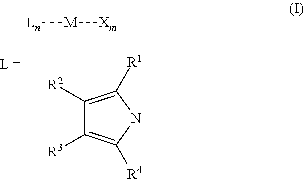
wherein R¹, R², R³, and R⁴ are independent of each other hydrogen, an alkyl group, an aryl group, or a SiA₃ group with A being alkyl or aryl group, and at least two of R¹, R², R³, and R⁴ are a SiA₃ group,
n is an integer from 1 to 4,
M is metal or semimetal,
X is a ligand which coordinates M, and
m is an integer from 0 to 4.

9. The compound according to claim 8, wherein R¹ and R⁴ are a SiA₃ group with A being alkyl or aryl group and R² and R³ are hydrogen.

10. The compound according to claim 8, wherein n is 2.

11. The compound according to claim 8, wherein M is Ba, Sr, Ni or Co.

12. A compound of general formula (II) 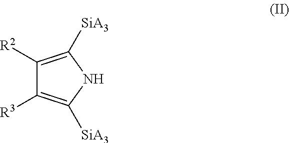
wherein A is an alkyl or an aryl group, R² and R³ are independent of each other hydrogen, an alkyl group, an aryl group, or a SiA₃ group with A being alkyl or aryl group.

13. A process for forming a film formation process on a solid substrate, comprising applying the compound of claim 8 to the solid substrate.
